(19) United States
(12) Patent Application Publication
(10) Pub. No.: US 2023/0317817 A1
(43) Pub. Date: Oct. 5, 2023

(54) SEMICONDUCTOR DEVICE AND POWER DEVICE

(71) Applicant: SEIKO EPSON CORPORATION, Tokyo (JP)

(72) Inventor: Hiroyuki SHIMADA, Chuo-shi (JP)

(73) Assignee: SEIKO EPSON CORPORATION, Tokyo (JP)

(21) Appl. No.: 18/191,177

(22) Filed: Mar. 28, 2023

(30) Foreign Application Priority Data
Mar. 29, 2022 (JP) 2022-053039

(51) Int. Cl. H01L 29/51; H01L 29/78

(52) U.S. Cl. CPC H01L 29/517; H01L 29/7827

(57) ABSTRACT

A semiconductor device includes a first semiconductor portion and a second semiconductor portion having the same conductivity type and arranged along a first direction, a third semiconductor portion provided between the first semiconductor portion and the second semiconductor portion and having a lower impurity concentration than the first semiconductor portion and the second semiconductor portion, a fourth semiconductor portion provided between the second semiconductor portion and the third semiconductor portion and having a lower impurity concentration than the first semiconductor portion and the second semiconductor portion, a gate insulating layer and a gate electrode provided in a second direction of the third semiconductor portion, the second direction intersecting the first direction, and a dielectric portion provided in the second direction of the fourth semiconductor portion, wherein the dielectric portion is formed of a material having a larger band gap and a larger relative permittivity than a material forming the fourth semiconductor portion, and a depletion layer is formed at the fourth semiconductor portion when a predetermined voltage is applied to the gate electrode.

The present application is based on, and claims priority from JP Application Serial Number 2022-053039, filed Mar. 29, 2022, the disclosure of which is hereby incorporated by reference herein in its entirety.

### BACKGROUND

### 1. Technical Field

The present disclosure relates to a semiconductor device and a power device.

### 2. Related Art

Semiconductor nanocolumns have attracted attention as a configuration of next-generation nanodevices for application to various semiconductor devices such as transistors and light sources. For example, by adopting a gate-all-around (GAA) structure in which a semiconductor nanocolumn is entirely surrounded by a gate electrode in a circumferential direction, a channel region of the semiconductor nanocolumn is surrounded by the gate electrode and brought into a completely depleted state, so that current controllability can be enhanced. The GAA structure makes it possible to achieve both a steep on-off switching characteristic with respect to time and an increase in density per unit area.

For example, JP-A-2014-503998 describes a transistor device including a nanowire, a gate dielectric surrounding the nanowire, and a gate conductor surrounding the gate dielectric.

In the transistor device as described above, it is desired to reduce the on-resistance.

### SUMMARY

A semiconductor device according to an aspect of the present disclosure includes
a first semiconductor portion and a second semiconductor portion having the same conductivity type and arranged along a first direction,
a third semiconductor portion provided between the first semiconductor portion and the second semiconductor portion and having a lower impurity concentration than the first semiconductor portion and the second semiconductor portion,
a fourth semiconductor portion provided between the second semiconductor portion and the third semiconductor portion and having a lower impurity concentration than the first semiconductor portion and the second semiconductor portion,
a gate insulating layer and a gate electrode provided in a second direction of the third semiconductor portion, the second direction intersecting the first direction, and
a dielectric portion provided in the second direction of the fourth semiconductor portion, wherein
the dielectric portion is formed of a material having a larger band gap and a larger relative permittivity than a material forming the fourth semiconductor portion and
a depletion layer is formed at the fourth semiconductor portion when a predetermined voltage is applied to the gate electrode.

A power device according to an aspect of the present disclosure includes
a first semiconductor portion and a second semiconductor portion having the same conductivity type and arranged along a first direction,
a third semiconductor portion provided between the first semiconductor portion and the second semiconductor portion and having a lower impurity concentration than the first semiconductor portion and the second semiconductor portion,
a fourth semiconductor portion provided between the second semiconductor portion and the third semiconductor portion and having a lower impurity concentration than the first semiconductor portion and the second semiconductor portion,
a gate insulating layer and a gate electrode provided in a second direction of the third semiconductor portion, the second direction intersecting the first direction, and
a dielectric portion provided in the second direction of the fourth semiconductor portion, wherein
the dielectric portion is formed of a material having a larger band gap and a larger relative permittivity than a material forming the fourth semiconductor portion and
a depletion layer is formed at the fourth semiconductor portion when a predetermined voltage is applied to the gate electrode.

### BRIEF DESCRIPTION OF THE DRAWINGS

FIG. 1 is a cross-sectional view schematically illustrating a semiconductor device according to an embodiment.

FIG. 2 is a plan view schematically illustrating the semiconductor device according to the embodiment.

FIG. 3 is a cross-sectional view schematically illustrating a manufacturing process of the semiconductor device according to the embodiment.

FIG. 4 is a cross-sectional view schematically illustrating a manufacturing process of the semiconductor device according to the embodiment.

FIG. 5 is a cross-sectional view schematically illustrating a manufacturing process of the semiconductor device according to the embodiment.

FIG. 6 is a cross-sectional view schematically illustrating a semiconductor device according to a modification example of the embodiment.

### DESCRIPTION OF EXEMPLARY EMBODIMENTS

A preferred embodiment of the present disclosure will be described in detail hereinafter with reference to the accompanying drawings. Note that the embodiment described hereinafter is not intended to unjustly limit the content of the present disclosure as set forth in the claims. In addition, all of the configurations described hereinafter are not necessarily essential constituent requirements of the present disclosure.

1. Semiconductor Device

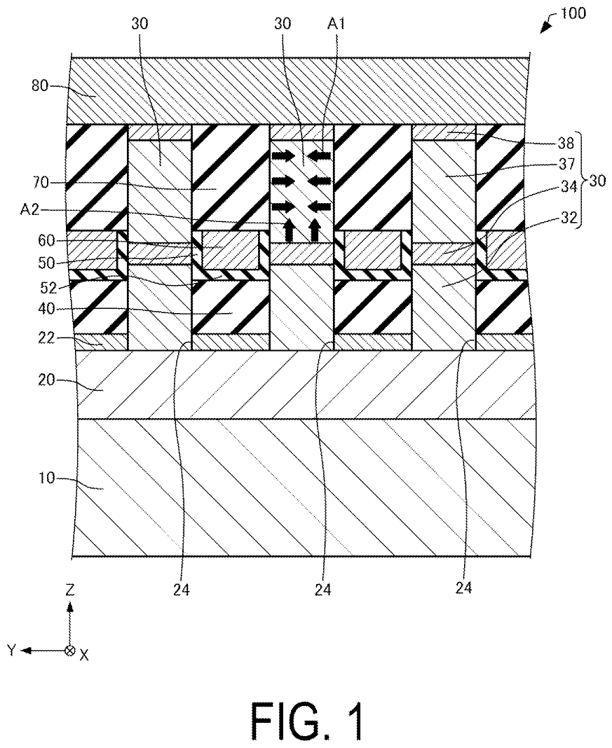

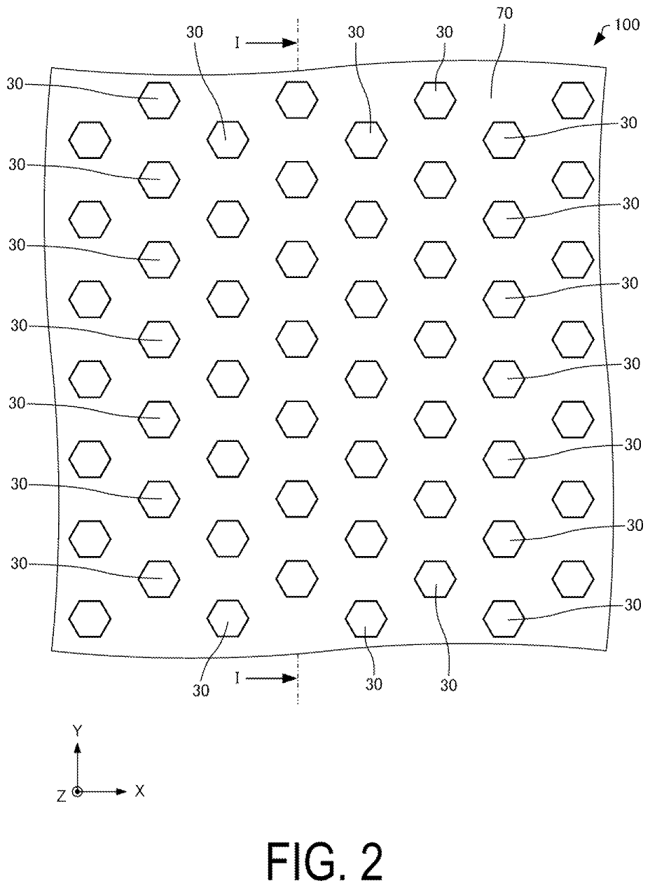

First, a semiconductor device according to the embodiment will be described with reference to the drawings. FIG. 1 is a cross-sectional view schematically illustrating a semiconductor device 100 according to the embodiment. FIG. 2 is a plan view schematically illustrating the semiconductor device 100 according to the embodiment. FIG. 1 is a cross-sectional view taken along line I-I in FIG. 2. In FIGS. 1 and 2, the X-axis, the Y-axis, and the Z-axis are illustrated as three axes orthogonal to each other.

As illustrated in FIGS. 1 and 2, the semiconductor device 100 includes a substrate 10, a buffer layer 20, a mask layer 22, a column portion 30, an insulating layer 40, a gate insulating layer 50, a gate electrode 60, a dielectric layer 70, and a drain electrode 80. The semiconductor device 100 is, for example, a power device. The semiconductor device 100 is, for example, a vertical metal oxide semiconductor field effect transistor (MOSFET). For convenience, the drain electrode 80 is omitted in FIG. 2.

Examples of the substrate 10 include a Si substrate, a GaN substrate, a sapphire substrate, and an SiC substrate.

As illustrated in FIG. 1, the buffer layer 20 is provided on the substrate 10. The buffer layer 20 is, for example, an n-type GaN layer or AlGaN layer doped with Si. The buffer layer 20 functions as, for example, a source. The buffer layer 20 is electrically coupled to, for example, a source pad (not illustrated). The source pad is electrically coupled to a source region 32 of the column portion 30 via the buffer layer 20.

In the present specification, in the stacking direction of a channel region 34 and a drain region 38 of the column portion 30, when the channel region 34 is used as a reference, a direction from the channel region 34 toward the drain region 38 is referred to as “upward”, and a direction from the channel region 34 toward the source region 32 is referred to as “downward”. In the illustrated example, the stacking direction of the channel region 34 and the drain region 38 is the Z-axis direction.

The mask layer 22 is provided on the buffer layer 20. The mask layer 22 is provided between the buffer layer 20 and the insulating layer 40. Examples of the mask layer 22 include a titanium layer, a silicon oxide layer, a titanium oxide layer, and an aluminum oxide layer. The mask layer 22 is provided with a plurality of opening portions 24. In the illustrated example, each opening portion 24 extends through the mask layer 22 in the Z-axis direction. The column portion 30 is located at the opening portion 24. The mask layer 22 functions as a mask for growing the column portion 30.

The column portion 30 is provided on the buffer layer 20. The column portion 30 is provided at the substrate 10 via the buffer layer 20. The column portion 30 has a column shape protruding upward from the buffer layer 20. In other words, the column portion 30 protrudes upward from the substrate 10 through the buffer layer 20. The column portion 30 is provided between the buffer layer 20 and the drain electrode 80. The column portion 30 is also called, for example, a nanocolumn, a nanowire, a nanorod, or a nanopillar. The planar shape of the column portion 30 is, for example, a polygon such as a hexagon or a circle. In the illustrated example in FIG. 2, the planar shape of the column portion 30 is a regular hexagon.

The diameter of the column portion 30 is, for example, 50 nm or more and 500 nm or less, and preferably 100 nm or more and 300 nm or less. When the diameter of the column portion 30 is 500 nm or less, the column portion 30 of high-quality crystal can be obtained.

When the planar shape of the column portion 30 is a circle, the “diameter of the column portion 30” is the diameter of the circle, and when the planar shape of the column portion 30 is not a circle, the “diameter of the column portion 30” is the diameter of the smallest enclosing circle. For example, when the planar shape of the column portion 30 is a polygon, the diameter of the column portion 30 is the diameter of the smallest circle including the polygon therein, and when the planar shape of the column portion 30 is an ellipse, the diameter of the column portion 30 is the diameter of the smallest circle including the ellipse therein.

For example, a plurality of the column portions 30 are provided. By providing the plurality of column portions 30, the semiconductor device 100 can handle a large current and is suitably used as a power device. The plurality of column portions 30 are separated from each other. The interval between the adjacent column portions 30 is, for example, 10 nm or more and 1 μm or less, preferably 0.5 times or more and 1.5 times or less of the diameter of the column portion 30, that is, 25 nm or more and 750 nm or less, and more preferably 400 nm or more and 600 nm or less. The plurality of column portions 30 are arranged, for example, at a predetermined pitch in a predetermined direction when viewed from the Z-axis direction. The plurality of column portions 30 are arranged in, for example, a triangular lattice pattern or a square lattice pattern. In the illustrated example, the plurality of column portions 30 are arranged in, for example, a regular triangular lattice pattern.

The “pitch of the column portions 30” is the distance between the centers of the column portions 30 adjacent in a predetermined direction. When the planar shape of the column portion 30 is a circle, the “center of the column portion 30” is the center of the circle, and when the planar shape of the column portion 30 is not a circle, the “center of the column portion 30” is the center of the smallest enclosing circle. For example, when the planar shape of the column portion 30 is a polygon, the center of the column portion 30 is the center of the smallest circle including the polygon therein, and when the planar shape of the column portion 30 is an ellipse, the center of the column portion 30 is the center of the smallest circle including the ellipse therein.

As illustrated in FIG. 1, the column portion 30 includes the source region 32, the channel region 34, a drift region 37, and the drain region 38.

The source region 32 is provided on the buffer layer 20. The source region 32 is provided between the buffer layer 20 and the channel region 34. The source region 32 is formed of a semiconductor layer. The material of the source region 32 is, for example, n-type GaN or AlGaN doped with Si. The impurity concentration of the source region 32 may be the same as the impurity concentration of the buffer layer 20.

The channel region 34 is provided on the source region 32. The channel region 34 is provided between the source region 32 and the drift region 37. The channel region 34 is formed of a semiconductor layer. The impurity concentration of the channel region 34 is lower than the impurity concentration of the source region 32 and the impurity concentration of the drain region 38. The impurity concentrations of the source region 32, the channel region 34, the drift region 37, and the drain region 38 are measured by, for example, atom probe analysis.

The material of the channel region 34 is, for example, an unintentionally doped (UID) type GaN or AlGaN not intentionally doped with impurities. Since the diameter of the column portion 30 is small, the channel region 34 can be brought into a completely depleted state even when the conductivity type of the channel region 34 is the UID type. A channel is formed at the channel region 34 by applying a predetermined voltage to the gate electrode 60. In the channel region 34, for example, an N-channel is formed.

The drift region 37 is provided on the channel region 34. The drift region 37 is provided between the channel region 34 and the drain region 38. The drift region 37 is formed of a semiconductor layer. The conductivity type of the drift region 37 is, for example, the same as that of the source region 32. The material of the drift region 37 is, for example, n-type GaN or AlGaN doped with Si.

The impurity concentration of the drift region 37 is lower than the impurity concentration of the source region 32 and the impurity concentration of the drain region 38. The impurity concentration of the drift region 37 may be the same as the impurity concentration of the channel region 34. Alternatively, the impurity concentration of the drift region 37 may be higher than the impurity concentration of the channel region 34. That is, the impurity concentration of the drift region 37 may be between the impurity concentration of the channel region 34 and the impurity concentration of the drain region 38. Providing the drift region 37 can improve the withstand voltage of the semiconductor device 100 in the off state.

The drain region 38 is provided on the drift region 37. The drain region 38 is provided between the drift region 37 and the drain electrode 80. The drain region 38 is formed of a semiconductor layer. The conductivity type of the drain region 38 is the same as that of the source region 32. The material of the drain region 38 is, for example, n-type GaN or AlGaN doped with Si.

The impurity concentration of the drain region 38 is higher than the impurity concentration of the drift region 37. The impurity concentration of the drain region 38 may be the same as the impurity concentration of the source region 32. The source region 32, the channel region 34, the drift region 37, and the drain region 38 are arranged along a first direction. In the illustrated example, the first direction is the +Z-axis direction. The source region 32, the channel region 34, the drift region 37, and the drain region 38 are stacked, for example, in the +Z-axis direction to form the column portion 30.

The insulating layer 40 is provided on the mask layer 22. The insulating layer 40 is provided between the substrate 10 and the gate electrode 60. The insulating layer 40 is provided between the source regions 32 of the adjacent column portions 30. The insulating layer 40 surrounds the source region 32 when viewed from the Z-axis direction. The insulating layer 40 is, for example, a spin-on-glass (SOG) layer.

The gate insulating layer 50 is provided at a side surface of the channel region 34 of the column portion 30. The side surface of the channel region 34 is constituted of, for example, an m-plane. The gate insulating layer 50 is provided in a second direction of the channel region 34, which intersects the first direction. In the illustrated example, the second direction is the +Y-axis direction and is orthogonal to the first direction that is the +Z-axis direction. The gate insulating layer 50 surrounds the channel region 34 when viewed from the Z-axis direction. The gate insulating layer 50 is provided between the channel region 34 and the gate electrode 60.

The gate insulating layer 50 is formed of, for example, a material having a larger band gap than the material forming the channel region 34. Further, the gate insulating layer 50 is formed of, for example, a material having a larger relative permittivity than the material forming the channel region 34. The material of the gate insulating layer 50 is, for example, transition metal oxide such as hafnium oxide (HfO₂), tantalum oxide (Ta₂O₅), yttrium oxide (Y₂O₃), zirconium oxide (ZrO₂), or lanthanum oxide (La₂O₃) and preferably hafnium oxide. Note that the material of the gate insulating layer 50 may be silicon oxide (SiO₂).

The gate electrode 60 is provided at the gate insulating layer 50. The gate electrode 60 is provided in the +Y-axis direction of the channel region 34. In the illustrated example, the gate electrode 60 surrounds the gate insulating layer 50 when viewed from the Z-axis direction. For example, the gate electrode 60 is provided at the insulating layer 40 via an insulating layer 52. The material of the insulating layer 52 is the same as that of the gate insulating layer 50. The gate electrode 60 is provided between the insulating layer 40 and the dielectric layer 70. The gate electrode 60 is provided between the channel regions 34 of the adjacent column portions 30.

The material of the gate electrode 60 is, for example, polysilicon doped with an impurity such as phosphorus or boron, or a metal. The semiconductor device 100 has a GAA structure. The gate electrode 60 is electrically coupled to a gate pad (not illustrated).

The dielectric layer 70 is provided on the gate insulating layer 50 and the gate electrode 60. The dielectric layer 70 is provided between the gate insulating layer 50 and the gate electrode 60, and the drain electrode 80. The dielectric layer 70 is provided in the +Y-axis direction of the drift region 37. In the illustrated example, the dielectric layer 70 surrounds the drift region 37. The dielectric layer 70 is provided between the drift regions 37 of the adjacent column portions 30.

The dielectric layer 70 is formed of a material having a larger band gap than the material forming the drift region 37. Furthermore, the dielectric layer 70 is formed of a material having a larger relative permittivity than the material forming the drift region 37. The material of the dielectric layer 70 is, for example, transition metal oxide such as hafnium oxide, tantalum oxide, yttrium oxide, zirconium oxide, or lanthanum oxide, and preferably hafnium oxide.

The dielectric layer 70 is formed of a material having a larger band gap and a larger relative permittivity than the material forming the drift region 37. Thus, when a predetermined voltage is applied to the gate electrode 60, a dielectric reduced surface field (RESURF) effect is exhibited, and a depletion layer is formed at the drift region 37 by an electric field generated at the dielectric layer 70. The semiconductor device 100 can have a pseudo super junction structure due to the dielectric RESURF effect. The predetermined voltage is a voltage for turning off the semiconductor device 100.

The depletion layer formed by the electric field generated at the dielectric layer 70 spreads from the side surfaces of the drift region 37 of the column portion 30 toward the center of the column portion 30 as indicated by the arrows A1 in FIG. 1. Further, as indicated by the arrows A2, a depletion layer spreading from the side of the channel region 34 toward the drift region 37 is also present. As described above, in the semiconductor device 100, since the depletion layer can spread in the vertical direction and the horizontal direction, the dielectric RESURF effect is exhibited.

The drain electrode 80 is provided on the drain region 38 and the dielectric layer 70. The drain electrode 80 is provided in the +Z-axis direction of the drain region 38. The drain region 38 may be in ohmic contact with the drain electrode 80.

The material of the drain electrode 80 is, for example, polysilicon doped with an impurity such as phosphorus or boron, or metal. The drain electrode 80 is electrically coupled to a drain pad (not illustrated). The drain pad is electrically coupled to the drain region 38 via the drain electrode 80.

The semiconductor device 100 is used as, for example, a power device and is applied to an inverter, a charger, a step-up transformer, a step-down transformer, a direct current (DC)/DC converter, an electric aircraft, an electric vehicle, and the like. The semiconductor device 100 may be used not as a power device but as a logic device, a high-frequency device, or the like.

The semiconductor device 100 has, for example, the following effects.

The semiconductor device 100 includes the source region 32 as a first semiconductor portion and the drain region 38 as a second semiconductor portion having the same conductivity type and arranged along the +Z-axis direction, the channel region 34 as a third semiconductor portion provided between the source region 32 and the drain region 38 and having a lower impurity concentration than the source region 32 and the drain region 38, the drift region 37 as a fourth semiconductor layer provided between the channel region 34 and the drain region 38 and having a lower impurity concentration than the source region 32 and the drain region 38, the gate insulating layer 50 and the gate electrode 60 provided in the +Y-axis direction of the channel region 34, and the dielectric layer 70 as a dielectric portion provided in the +Y-axis direction of the drift region 37. The dielectric layer 70 is formed of a material having a larger band gap and a larger relative permittivity than the material forming the drift region 37, and when a predetermined voltage is applied to the gate electrode 60, a depletion layer is formed at the drift region 37 by an electric field generated at the dielectric layer 70.

Thus, in the semiconductor device 100, the dielectric RESURF effect in which the depletion layer spreads from the side surfaces of the drift region 37 of the column portion 30 toward the center of the column portion 30 as indicated by the above-described arrows A1 can be increased as compared with, for example, a case where the dielectric constant of the dielectric layer is equal to or lower than the dielectric constant of the drift region. This can improve the withstand voltage. As a result, it is possible to increase the impurity concentration of the drift region 37, which can reduce the on-resistance.

Furthermore, in the semiconductor device 100, the insulating property of the dielectric layer 70 can be enhanced as compared with, for example, a case where the band gap of the dielectric layer is equal to or smaller than the band gap of the drift region. This can reduce a leak current.

Furthermore, in the semiconductor device 100, since the impurity concentration of the channel region 34 is lower than the impurity concentrations of the source region 32 and the drain region 38, the carrier mobility of the channel region 34 can be increased. For example, when an N-channel is formed at the channel region 34, the electron mobility of the channel region 34 can be increased. This can reduce the on-resistance.

Furthermore, the semiconductor device 100 can be manufactured more easily than in a case where a p-type semiconductor layer having a conductivity type different from those of the source region 32 and the drain region 38 is provided instead of the dielectric layer 70. For example, when a p-type semiconductor layer is provided instead of the dielectric layer 70 to form a super junction structure, it is necessary to control the impurity concentration of the p-type semiconductor layer with high accuracy, which complicates the manufacturing process.

Furthermore, in the off state of the semiconductor device 100, the potential difference between the gate electrode 60 and the drain region 38 is larger than the potential difference between the gate electrode 60 and the source region 32. Thus, the dielectric RESURF effect can be increased as compared with a case where the dielectric layer is provided in the +Y-axis direction of the source region.

In the semiconductor device 100, the source region 32, the channel region 34, and the drift region 37 are stacked in the +Z-axis direction to form the column portion 30. Thus, in the semiconductor device 100, a crystal defect caused by the lattice constant difference between the substrate 10 and the buffer layer 20 is bent in the source region 32 at the side surface of the column portion 30, which can reduce the possibility that the crystal defect reaches the channel region 34 and the drift region 37, as compared with a case where the source region, the channel region, and the drift region do not constitute the column portion. Thus, the channel region 34 and the drift region 37 can have high-quality crystallinity. In the illustrated example, since the drain region 38 also constitutes the column portion 30, the drain region 38 can also have high-quality crystallinity.

In the semiconductor device 100, when viewed from the Z-axis direction, the gate insulating layer 50 surrounds the channel region 34, and the gate electrode 60 surrounds the gate insulating layer 50. Thus, in the semiconductor device 100, the channel region 34 can be brought into a completely depleted state.

In the semiconductor device 100, the material of the dielectric layer 70 is transition metal oxide. Thus, in the semiconductor device 100, it is easy to achieve the dielectric layer 70 having a larger band gap and a larger relative permittivity than the drift region 37.

In the semiconductor device 100, the material of the dielectric layer 70 is hafnium oxide. Thus, in the semiconductor device 100, the dielectric layer 70 can be formed by an atomic layer deposition (ALD) method. Thereby, for example, the dielectric layer 70 can be formed without a void even between the adjacent column portions 30.

In the semiconductor device 100, the gate insulating layer 50 is formed of a material having a larger band gap and a larger relative permittivity than the material forming the channel region 34. Thus, in the semiconductor device 100, controllability of a threshold voltage can be improved as compared with, for example, a case where the dielectric constant of the gate insulating layer is equal to or smaller than the dielectric constant of the channel region. Furthermore, the insulating property of the gate insulating layer 50 can be improved as compared with, for example, a case where the band gap of the gate insulating layer is equal to or smaller than the band gap of the channel region.

In the semiconductor device 100, the material of the gate insulating layer 50 is transition metal oxide. Thus, in the semiconductor device 100, it is easy to achieve the gate insulating layer 50 having a larger band gap and a larger relative permittivity than the channel region 34.

In the semiconductor device 100, the material of the gate insulating layer 50 is hafnium oxide. Thus, in the semiconductor device 100, the gate insulating layer 50 can be formed by an ALD method. Thereby, for example, the gate insulating layer 50 can be formed without a void even between the adjacent column portions 30.

2. Method for Manufacturing Semiconductor Device

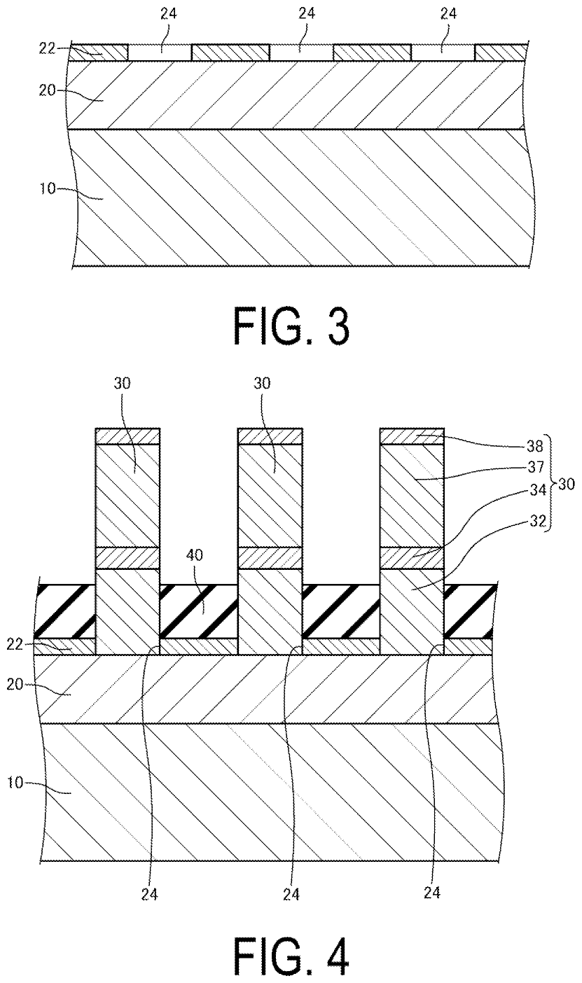

Next, a method for manufacturing the semiconductor device 100 according to the embodiment will be described with reference to the drawings. FIGS. 3 to 5 are cross-sectional views schematically illustrating manufacturing processes of the semiconductor device 100 according to the embodiment.

As illustrated in FIG. 3, the buffer layer 20 is epitaxially grown on the substrate 10. Examples of the method for epitaxial growth include a metal organic chemical vapor deposition (MOCVD) method and a molecular beam epitaxy (MBE) method. The buffer layer 20 is grown while being doped with impurities.

Next, the mask layer 22 is formed on the buffer layer 20. The mask layer 22 is formed by, for example, an electron beam evaporation method, a sputtering method, or the like.

Next, the mask layer 22 is patterned and the plurality of opening portions 24 are formed. The patterning is performed by, for example, electron beam lithography and dry etching.

As illustrated in FIG. 4, the source region 32, the channel region 34, the drift region 37, and the drain region 38 are epitaxially grown in this order on the buffer layer 20 using the mask layer 22 as a mask. Examples of the method for epitaxial growth include an MOCVD method and an MBE method. The source region 32 and the drain region 38 are grown while being doped with impurities. By this step, the plurality of column portions 30 can be formed.

Next, the insulating layer 40 is formed on the mask layer 22 between the source regions 32 of the adjacent column portions 30. The insulating layer 40 is formed by, for example, an ALD method, a chemical vapor deposition (CVD) method, or a spin-on-glass (SOG) method.

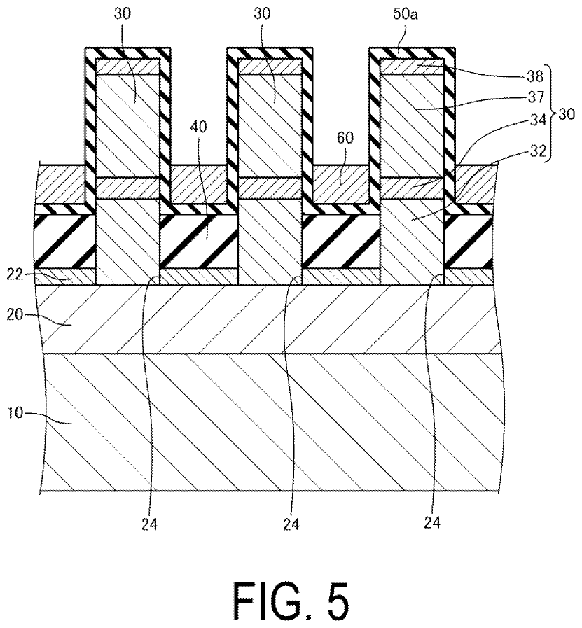

As illustrated in FIG. 5, an insulating layer 50a is formed on the insulating layer 40 so as to cover the column portion 30. The insulating layer 50a is formed by, for example, an ALD method or a CVD method. In the illustrated example, the insulating layer 50a is formed at the side surfaces and the upper surface of the column portion 30.

Next, the gate electrode 60 is formed on the insulating layer 50a. The gate electrode 60 is formed by, for example, a CVD method, a sputtering method, or a vacuum deposition method.

As illustrated in FIG. 1, the insulating layer 50a is partially removed by etching. Thus, the gate insulating layer 50 is formed between the channel region 34 and the gate electrode 60. The drain region 38 is exposed by the etching.

Next, the dielectric layer 70 is formed on the gate insulating layer 50 and the gate electrode 60. The dielectric layer 70 is formed by, for example, an ALD method or a CVD method.

Next, the drain electrode 80 is formed on the drain region 38 and the dielectric layer 70. The drain electrode 80 is formed by, for example, a CVD method, a sputtering method, or a vacuum deposition method.

Through the processes described above, the semiconductor device 100 can be manufactured.

3. Modification Example of Semiconductor Device

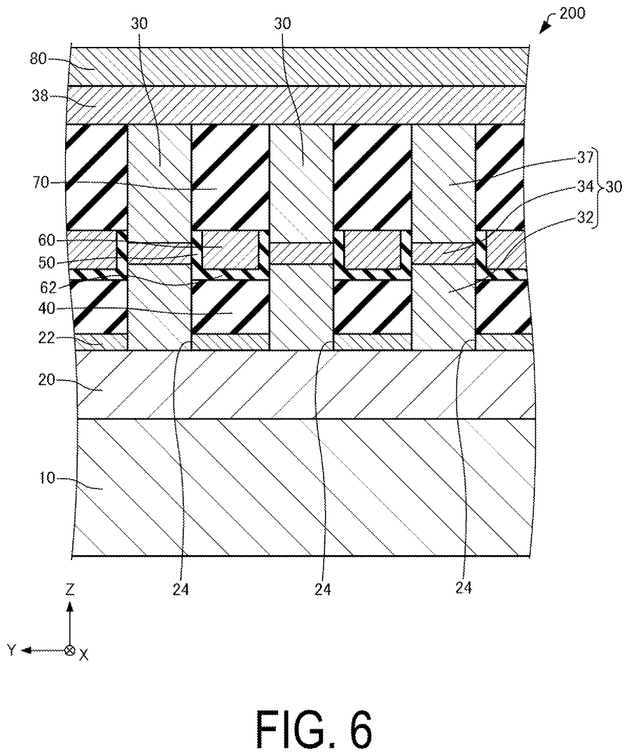

Next, a semiconductor device according to a modification example of the embodiment will be described with reference to the drawings. FIG. 6 is a cross-sectional view schematically illustrating a semiconductor device 200 according to the modification example of the embodiment. Hereinafter, in the semiconductor device 200 according to the modification example of the embodiment, members having the same functions as the constituent members of the semiconductor device 100 according to the above-described embodiment are denoted by the same reference signs, and detailed description thereof will be omitted.

In the above-described semiconductor device 100, as illustrated in FIG. 1, the drain region 38 constitutes the column portion 30.

On the other hand, in the semiconductor device 200, as illustrated in FIG. 6, a drain region 38 does not constitute a column portion 30. The column portion 30 includes a source region 32, a channel region 34, and a drift region 37.

The drain region 38 is further provided in the +Z-axis direction of a dielectric layer 70. The drain region 38 is provided on the drift region 37 and the dielectric layer 70. The drain region 38 is provided between the drift region 37 and the dielectric layer 70, and a drain electrode 80. The drain region 38 is provided over a plurality of the column portions 30. When viewed in the stacking direction, the drain region 38 overlaps the plurality of column portions 30. When viewed in the stacking direction, the drain electrode 80 overlaps the plurality of column portions 30.

The semiconductor device 200 includes the drain electrode 80 provided in the +Z-axis direction of the drift region 37, and the drain region 38 is further provided in the +Z-axis direction of the dielectric layer 70. Thus, in the semiconductor device 200, it is possible to increase the contact area between the drain region 38 and the drain electrode 80 as compared with a case where the drain region is not provided in the +Z-axis direction of the dielectric layer. This can reduce the contact resistance between the drain region 38 and the drain electrode 80. Since the contact resistance between the semiconductor layer and the metal electrode is typically high, it is important to increase the contact area.

The above-described embodiment and the modification example are mere examples, and the present disclosure is not limited thereto. For example, each embodiment and each modification example may be combined as appropriate.

The present disclosure includes substantially the same configuration as that described in the embodiment, for example, a configuration having the same function, method, and result or a configuration having the same object and effect. In addition, the present disclosure includes a configuration in which a portion not essential in the configuration described in the embodiment is replaced. In addition, the present disclosure includes a configuration that exerts the same operational effect or a configuration that can fulfill the same object as the configuration described in the embodiment. In addition, the present disclosure includes a configuration in which the related art is added to the configuration described in the embodiment.

The following contents are derived from the above-described embodiment and modification example.

According to an aspect, a semiconductor device includes
a first semiconductor portion and a second semiconductor portion having the same conductivity type and arranged along a first direction,
a third semiconductor portion provided between the first semiconductor portion and the second semiconductor portion and having a lower impurity concentration than the first semiconductor portion and the second semiconductor portion,
a fourth semiconductor portion provided between the second semiconductor portion and the third semiconductor portion and having a lower impurity concentration than the first semiconductor portion and the second semiconductor portion,
a gate insulating layer and a gate electrode provided in a second direction of the third semiconductor portion, the second direction intersecting the first direction, and
a dielectric portion provided in the second direction of the fourth semiconductor portion, wherein
the dielectric portion is formed of a material having a larger band gap and a larger relative permittivity than a material forming the fourth semiconductor portion and
a depletion layer is formed at the fourth semiconductor portion when a predetermined voltage is applied to the gate electrode.

With such semiconductor layers, the on-resistance can be reduced.

In an aspect of the semiconductor device,
the first semiconductor portion, the third semiconductor portion, and the fourth semiconductor portion may be stacked in the first direction to form a column portion.

With such semiconductor layers, it is possible to reduce the possibility that a crystal defect reaches the third semiconductor portion and the fourth semiconductor portion.

In an aspect of the semiconductor device,
the gate insulating layer may surround the third semiconductor portion when viewed from the first direction and
the gate electrode may surround the gate insulating layer.

With such semiconductor layers, the third semiconductor portion can be brought into a completely depleted state.

In an aspect of the semiconductor device,
the first semiconductor portion may constitute a source region and
the second semiconductor portion may constitute a drain region.

With such semiconductor layers, the dielectric RESURF effect can be increased.

In an aspect of the semiconductor device,
the material of the dielectric portion may be transition metal oxide.

With such semiconductor layers, it is easy to achieve the dielectric portion having a larger band gap and a larger relative permittivity than the second semiconductor portion.

In an aspect of the semiconductor device, the material of the dielectric portion may be hafnium oxide.

With such semiconductor layers, the dielectric portion can be formed by an ALD method.

In an aspect of the semiconductor device,
the gate insulating layer may be formed of a material having a larger band gap and a larger relative permittivity than a material forming the third semiconductor portion.

With such semiconductor layers, controllability of the threshold voltage can be improved.

In an aspect of the semiconductor device,
a material of the gate insulating layer may be transition metal oxide.

With such semiconductor layers, it is easy to achieve the gate insulating layer having a larger band gap and a larger relative permittivity than the third semiconductor portion.

In an aspect of the semiconductor device,
a material of the gate insulating layer may be hafnium oxide.

With such semiconductor layers, the gate insulating layer can be formed by an ALD method.

According to an aspect, the semiconductor device may further include
an electrode provided in the first direction of the second semiconductor portion, wherein
the second semiconductor portion may be further provided in the first direction of the dielectric portion.

With such semiconductor layers, the contact resistance between the second semiconductor portion and the electrode can be reduced.

According to an aspect, a power device includes a first semiconductor portion and a second semiconductor portion having the same conductivity type and arranged along a first direction,
a third semiconductor portion provided between the first semiconductor portion and the second semiconductor portion and having a lower impurity concentration than the first semiconductor portion and the second semiconductor portion,
a gate insulating layer and a gate electrode provided in a second direction of the third semiconductor portion, the second direction intersecting the first direction, and
a dielectric portion provided in the second direction of the second semiconductor portion, wherein
the dielectric portion is formed of a material having a larger band gap and a larger relative permittivity than a material forming the second semiconductor portion and
a depletion layer is formed at the second semiconductor portion by an electric field generated at the dielectric layer when a predetermined voltage is applied to the gate electrode.

With such a power device, the on-resistance can be reduced.

What is claimed is:

1. A semiconductor device comprising:
a first semiconductor portion and a second semiconductor portion having the same conductivity type and arranged along a first direction;
a third semiconductor portion provided between the first semiconductor portion and the second semiconductor portion and having a lower impurity concentration than the first semiconductor portion and the second semiconductor portion;
a fourth semiconductor portion provided between the second semiconductor portion and the third semiconductor portion and having a lower impurity concentration than the first semiconductor portion and the second semiconductor portion;
a gate insulating layer and a gate electrode provided in a second direction of the third semiconductor portion, the second direction intersecting the first direction; and
a dielectric portion provided in the second direction of the fourth semiconductor portion, wherein
the dielectric portion is formed of a material having a larger band gap and a larger relative permittivity than a material forming the fourth semiconductor portion and
a depletion layer is formed at the fourth semiconductor portion when a predetermined voltage is applied to the gate electrode.

2. The semiconductor device according to claim 1, wherein the first semiconductor portion, the third semiconductor portion, and the fourth semiconductor portion are stacked in the first direction to form a column portion.

3. The semiconductor device according to claim 2, wherein
the gate insulating layer surrounds the third semiconductor portion when viewed from the first direction and
the gate electrode surrounds the gate insulating layer.

4. The semiconductor device according to claim 1, wherein
the first semiconductor portion constitutes a source region and
the second semiconductor portion constitutes a drain region.

5. The semiconductor device according to claim 1, wherein the dielectric portion is composed of transition metal oxide.

6. The semiconductor device according to claim 1, wherein the dielectric portion is composed of hafnium oxide.

7. The semiconductor device according to claim 1, wherein the gate insulating layer is formed of a material having a larger band gap and a larger relative permittivity than a material forming the third semiconductor portion.

8. The semiconductor device according to claim 1, wherein the gate insulating layer is composed of transition metal oxide.

9. The semiconductor device according to claim 1, wherein the gate insulating layer is composed of hafnium oxide.

10. The semiconductor device according to claim 1, further comprising
an electrode provided in the first direction of the second semiconductor portion, wherein
the second semiconductor portion is further provided in the first direction of the dielectric portion.

11. A power device comprising:
a first semiconductor portion and a second semiconductor portion having the same conductivity type and arranged along a first direction;
a third semiconductor portion provided between the first semiconductor portion and the second semiconductor portion and having a lower impurity concentration than the first semiconductor portion and the second semiconductor portion;
a fourth semiconductor portion provided between the second semiconductor portion and the third semiconductor portion and having a lower impurity concentration than the first semiconductor portion and the second semiconductor portion;
a gate insulating layer and a gate electrode provided in a second direction of the third semiconductor portion, the second direction intersecting the first direction; and
a dielectric portion provided in the second direction of the fourth semiconductor portion, wherein
the dielectric portion is formed of a material having a larger band gap and a larger relative permittivity than a material forming the fourth semiconductor portion and
a depletion layer is formed at the fourth semiconductor portion when a predetermined voltage is applied to the gate electrode.
